(19) United States
(12) Patent Application Publication
(10) Pub. No.: US 2012/0153975 A1
(43) Pub. Date: Jun. 21, 2012

(54) DRIVER CIRCUIT

(75) Inventors: Yasuyuki Arai, Tokyo (JP); Shoji Kojima, Tokyo (JP)

(73) Assignee: ADVANTEST CORPORATION, Tokyo (JP)

(21) Appl. No.: 13/324,984

(22) Filed: Dec. 13, 2011

(30) Foreign Application Priority Data
Dec. 15, 2010 (JP) 2010-279738

(51) Int. Cl. G01R 31/26; H03B 1/00

(52) U.S. Cl. 324/750.01; 327/109

(57) ABSTRACT

A branch circuit branches an input signal to be transmitted into multiple paths. Each timing adjustment circuit applies a delay to at least one from among a positive edge and a negative edge of a signal to be transmitted, which has been branched into a corresponding path. A combining output circuit combines the output signals of the multiple timing adjustment circuits, and outputs the signal thus combined to a transmission line.

### BACKGROUND OF THE INVENTION

1. Field of the Invention

The present invention relates to a driver circuit configured to output a signal via a transmission line.

2. Description of the Related Art

In order to evaluate and test a semiconductor device (DUT: device under test), a semiconductor test apparatus (which will simply be referred to as the “test apparatus”) is employed. The test apparatus is configured to apply a test signal to a DUT, and, while controlling the state of the DUT, to compare an output signal of the DUT with an expected value, so as to judge the quality of the DUT. Such a test apparatus mounts a driver circuit configured to output a test signal to such a DUT.

There is a demand for such a driver mounted on a test apparatus to have a function for adjusting a positive edge (slope) transition time (rising time) Tr and a negative edge transition time (falling time) Tf.

### RELATED ART DOCUMENTS

### Patent Documents

### [Patent Document 1]

Japanese Patent Application Laid Open No. H05-5771

### [Patent Document 2]

Japanese Patent Application Laid Open No. H06-338777

### [Patent Document 3]

U.S. Pat. No. 4,488,062

### [Patent Document 4]

U.S. Pat. No. 4,794,552

A frontend comprising such a driver and a comparator included in a test apparatus (which is also referred to as “pin electronics”) is integrated using the CMOS process. However, such driver circuits described in Patent documents 1 through 4 are each configured to adjust the rising time Tr and the falling time Tf, which requires the driver circuit to include capacitors and diodes as additional components. This leads to low compatibility with the CMOS process, resulting in a problem of an increase in the circuit scale.

### SUMMARY OF THE INVENTION

The present invention has been made in view of such a situation. Accordingly, it is an exemplary purpose of an embodiment of the present invention to provide a driver circuit configured to be capable of adjusting at least one from among the waveform of a positive edge and the waveform of a negative edge.

An embodiment of the present invention relates to a driver circuit configured to output a signal to a transmission line. The driver circuit comprises: a branch circuit configured to branch a signal to be transmitted into multiple paths; multiple timing adjustment circuits, respectively provided to the multiple paths, which are each configured to apply a delay to at least one from among a positive edge and a negative edge of the signal to be transmitted thus branched into a corresponding path; and a combining output circuit configured to combine output signals of the multiple timing adjustment circuits, and to output the combined signal to the transmission line.

Such an embodiment is capable of controlling the waveform of the combined signal according to the amounts of delay applied by the respective timing adjustment circuits. Thus, such an arrangement is capable of controlling the transition time Tr and/or Tf.

Also, the combining output circuit may comprise: a voltage source configured to generate a predetermined voltage; a first resistor configured to receive the predetermined voltage via its first terminal; a second resistor configured to receive the predetermined voltage via its first terminal; multiple differential pairs, provided to the multiple respective paths, which each comprise a first transistor arranged such that its first terminal is connected to a second terminal of the first resistor, and a second transistor arranged such that its first terminal is connected to a second terminal of the second resistor and its second terminal is connected to a second terminal of the first transistor so as to form a common second terminal; a constant current circuit configured to supply a tail current to the multiple differential pairs; and multiple differential conversion circuits, provided to the multiple respective paths, which are each configured to convert an output signal of the corresponding timing adjustment circuit into a differential signal, to output one component of the differential signal to a control terminal of the first transistor that forms the corresponding differential pair, and to output the other component of the differential signal to a control terminal of the second transistor that forms the corresponding differential pair.

By providing the output stage of the driver having a CML (Current Mode Logic) type configuration, by providing a differential pair for each path, and by combining the currents that flow through the respective differential pairs, such an arrangement is capable of appropriately combining the output signals of the multiple timing adjustment circuits. Such a configuration has an advantage of very high compatibility with the CMOS process.

Also, the constant current circuit may comprise a single constant current source that is shared by the multiple differential pairs.

Also, the constant current circuit may comprise multiple constant current sources, provided to the multiple respective differential pairs, which are each configured to supply a predetermined tail current to the corresponding differential pair.

Also, the combining output circuit may be configured to output, to the transmission line, a signal that is output from the second terminal of the second resistor. That is to say, such an arrangement may have a single-ended output configuration.

Also, the combining output circuit may be configured to output, to a differential transmission line, a signal that is output from the second terminal of the second resistor and a signal that is output from the second terminal of the first resistor. That is to say, such an arrangement may have a differential output configuration.

Also, the combining output circuit may comprise: multiple buffer circuits, provided to the multiple respective paths, which are each configured to receive an output signal of the corresponding timing adjustment circuit; multiple combining resistors, provided to the multiple respective paths, which are each arranged such that an output signal of the corresponding buffer circuit is received via a first terminal of the corresponding combining resistor, and such that their second terminals are connected together so as to form a common second terminal; and an output buffer configured to receive a signal output via the common second terminal obtained by connecting together the second terminals of the multiple combining resistors, and to output the signal thus received to the transmission line.

With such an embodiment, the signals are combined using resistors. Thus, such an arrangement provides high compatibility with the CMOS process.

Also, the timing adjustment circuit may comprise a delay circuit configured to delay an input signal.

Such an arrangement allows the driver circuit to output a signal having a positive edge waveform and a negative edge waveform that are symmetrical.

Also, the timing adjustment circuit may comprise a pulse width adjustment circuit configured to apply separate respective delays to a positive edge and a negative edge of the input signal, thereby adjusting the pulse width.

Such an arrangement is capable of independently controlling the positive edge waveform and the negative edge waveform of the output signal of the driver circuit.

Also, the timing adjustment circuits may each comprise: a delay circuit configured to delay an input signal; and a pulse width adjustment circuit configured to apply separate delays to a positive edge and a negative edge of the input signal, thereby adjusting the pulse width of the signal. With such an arrangement, the delay circuit and the pulse width adjustment circuit of each timing adjustment circuit may be arranged in series on the corresponding path.

Such an arrangement provides an improved degree of freedom in controlling the positive edge waveform and the negative edge waveform of the output signal of the driver circuit.

Another embodiment of the present invention relates to a test apparatus configured to test a device under test. The test apparatus comprises a driver circuit according to any one of the aforementioned embodiments, configured to output a signal that corresponds to a test pattern to the device under test via a transmission line.

Such an embodiment is capable of changing the waveform of a test signal to be supplied to a device under test. Thus, such an arrangement allows various kinds of tests to be performed.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram which shows a configuration of a driver circuit according to an embodiment;

FIG. 2 is a first time chart which shows the operation of the driver circuit shown in FIG. 1;

FIG. 3 is a circuit diagram which shows a configuration of a driver circuit including a combining output circuit having a CML configuration;

FIG. 4 is a circuit diagram which shows a modification of the combining output circuit shown in FIG. 3;

FIGS. 5A and 5B are block diagrams showing a driver circuit according to a first modification and a driver circuit according to a second modification, respectively;

FIGS. 6A and 6B are time charts each showing the operation of the driver circuit shown in FIG. 5A;

FIG. 7 is a time chart which shows the operation of the driver circuit shown in FIG. 5B;

FIG. 8 is a circuit diagram which shows another example configuration of the combining output circuit; and

FIG. 9 is a block diagram which shows a configuration of a test apparatus including a driver circuit according to an embodiment.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not substantially affect the electric connection therebetween, or that does not damage the functions or effects of the connection therebetween, in addition to a state in which the member A is physically and directly connected to the member B. Similarly, the state represented by the phrase “the member C is provided between the member A and the member B” includes a state in which the member A is indirectly connected to the member C, or the member B is indirectly connected to the member C via another member that does not substantially affect the electric connection therebetween, or that does not damage the functions or effects of the connection therebetween, in addition to a state in which the member A is directly connected to the member C, or the member B is directly connected to the member C.

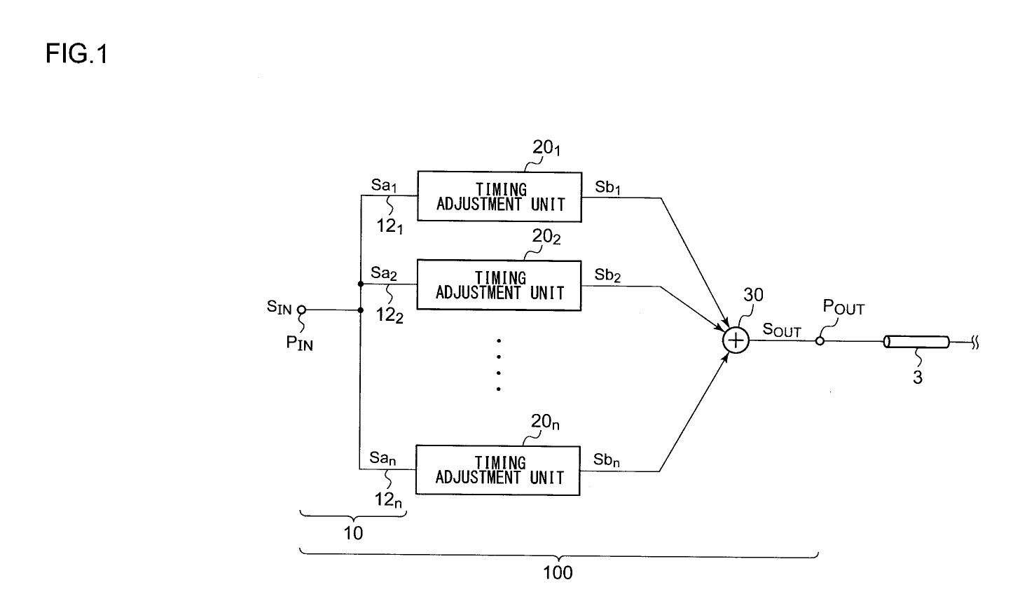

FIG. 1 is a block diagram which shows a configuration of a driver circuit 100 according to an embodiment. The driver circuit 100 is configured to receive an input signal S_{IN} via its input terminal P_{IN}, to control the waveform of the input signal S_{IN}, and to output an output signal via its output terminal P_{OUT}. An unshown reception device is connected to the output terminal P_{OUT} via a transmission line 3.

The driver circuit 100 mainly includes a branch circuit 10, multiple timing adjustment circuits 20, and a combining output circuit 30.

The branch circuit 10 branches the input signal S_{IN} to be transmitted into multiple paths 12₁ through 12ₙ. Here, “n” represents an integer of 2 or more, and represents the number of paths.

The multiple timing adjustment circuits 20₁ through 20ₙ are respectively provided to the multiple paths 12₁ through 12ₙ. The i-th timing adjustment circuit 20ᵢ (1≦i≦n) applies a delay to at least one from among a positive edge and a negative edge of the corresponding input signal Saᵢ that has been branched into the corresponding path 12ᵢ.

For example, the timing adjustment circuit 20 may include a delay circuit VD configured to delay its input signal. The delay circuit VD is preferably configured as a variable delay circuit which is capable of adjusting the amount of delay. The delay circuit applies the same delay to the overall waveform of the input signal. That is to say, such an arrangement applies the same delay to the positive edge and the negative edge of the input signal Sa that has been branched. As such a delay circuit, such an arrangement may employ a circuit described in the pamphlet International Publication WO 2006/025285, etc. Also, delay circuits having different configurations may be employed.

The combining output circuit 30 combines the output signals Sb₁ through Sbₙ of the multiple timing adjustment circuits 20₁ through 20ₙ, and outputs the signal S_{OUT} that has been combined to the transmission line 3.

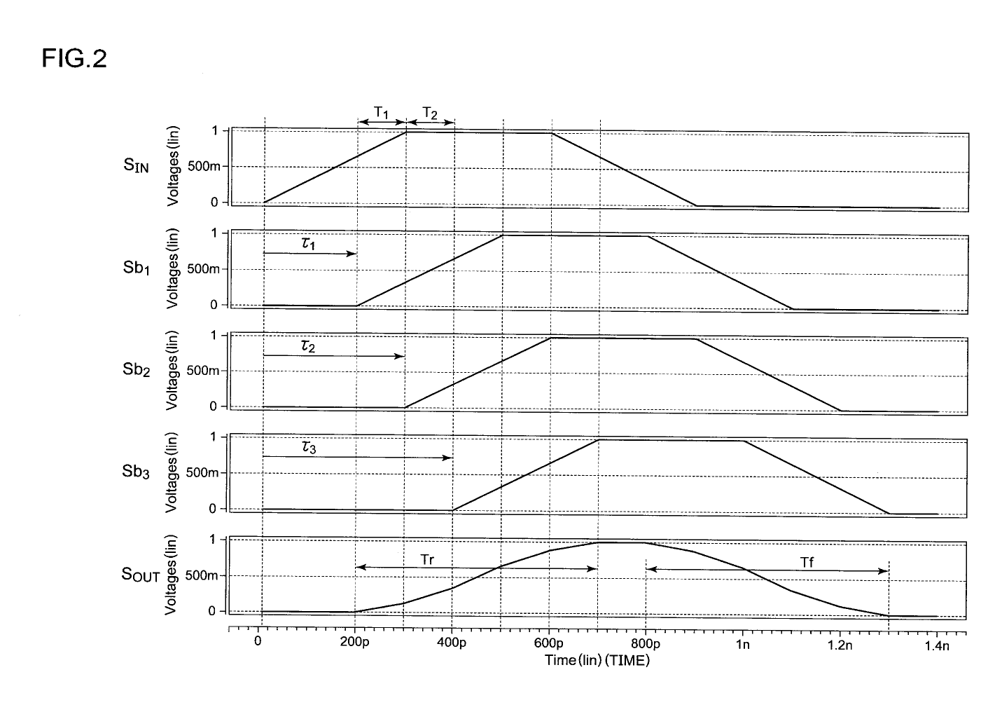

The above is the basic configuration of the driver circuit 100. Next, description will be made regarding the operation thereof. FIG. 2 is a first time chart which shows the operation of the driver circuit 100 shown in FIG. 1. This time chart shows an arrangement in which n=3. By setting different amounts of delay τ1, τ2, and τ3, for the respective timing adjustment circuits 20, the output signal S_{OUT} has a positive edge having multiple inflection points. The slope of each segment between two adjacent inflection points is determined according to the number of branched signals Sb in which there are positive edges that are included in the segment. For example, a segment T1 includes a positive edge of a single signal Sb₁. A segment T2 includes two positive edges (slopes) of the two respective signals Sb₁ and Sb₂, and accordingly, the slope of the output signal S_{OUT} in the segment T2 is double the slope of the output signal S_{OUT} in the segment T1.

As described above, with the driver circuit 100 shown in FIG. 1, by controlling the amounts of delay to be applied by the respective timing adjustment circuits 20, such an arrangement is capable of controlling the waveform of the positive edge of the output signal S_{OUT}, i.e., the transition time Tr of the positive edge of the output signal S_{OUT}.

Furthermore, the resolution of the waveform control is determined according to the number n of paths that are branched. In other words, the number of paths may preferably be determined according to the required resolution.

Similar processing is performed for the negative edge of the input signal S_{IN}, thereby controlling the waveform of the negative edge of the output signal S_{OUT}, i.e., the transition time Tf. Furthermore, in a case in which the timing adjustment circuits 20 are each configured as a delay circuit, such an arrangement can provide the output signal S_{OUT} in which the waveforms of the positive edge and the negative edge are symmetrical.

When the input signal S_{IN} and the output signal S_{OUT} transit at high speed, the output stage of the driver circuit 100 preferably has a CML-type configuration. Description will be made regarding a specific example configuration of the combining output circuit 30 having such a CML-type configuration.

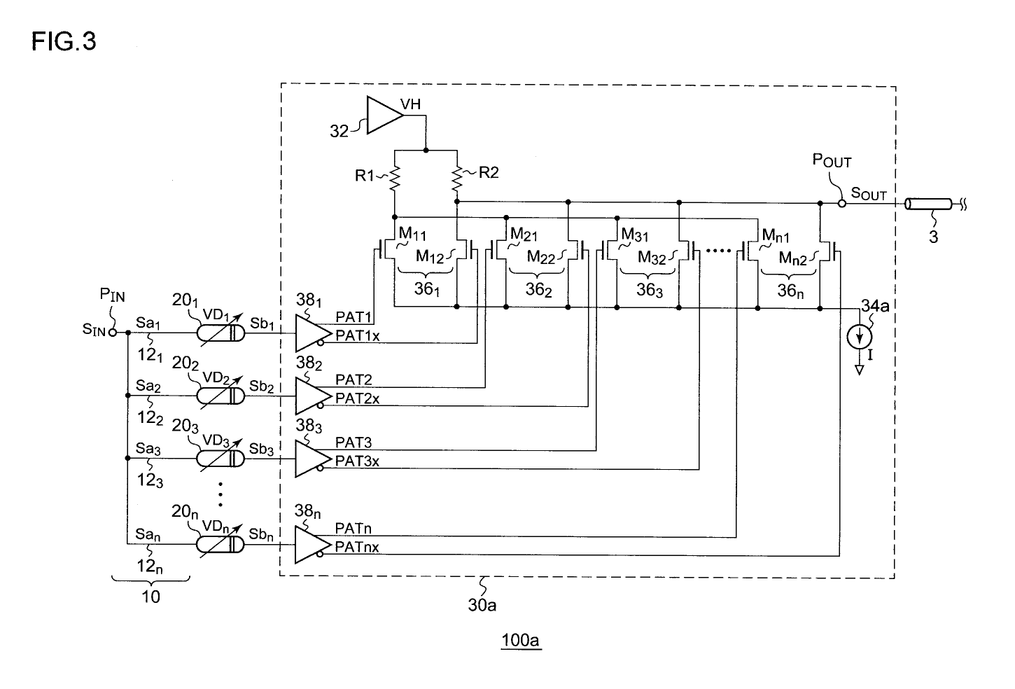

FIG. 3 is a circuit diagram which shows a configuration of a driver circuit 100a including a combining output circuit 30a having a CML-type configuration.

The combining output circuit 30a includes a voltage source 32, a constant current circuit 34a, multiple differential pairs 36, multiple differential conversion circuits 38, a first resistor R1, and a second resistor R2.

The voltage source 32 is configured to generate a predetermined voltage VH. The voltage VH thus generated is applied to each of the first terminals of the first resistor R1 and the second resistor R2. The multiple differential pairs 36₁ through 36ₙ are respectively provided to the multiple paths 12₁ through 12ₙ. The i-th differential pair 36, includes a first transistor Mᵢ₁ and a second transistor Mᵢ₂. The first terminal (e.g., drain) of the first transistor Mᵢ₁ is connected to the second terminal of the first resistor R1. The first terminal (drain) of the second transistor Mᵢ₂ is connected to the second terminal of the second resistor R2. The second terminal (source) of the second transistor Mᵢ₂ is connected to the second terminal (source) of the corresponding first transistor Mᵢ₁. The first transistor Mᵢ₁ and the second transistor M₁₂, which belong to the same differential pair 36, are designed to have the same transistor size.

The constant current circuit 34a is configured to supply a tail current I to the multiple differential pairs 36₁ through 36ₙ. In FIG. 3, the sources of the transistors included in the multiple differential pairs are connected together so as to form a common source terminal. The constant current circuit 34a includes a single constant current source arranged as a common constant current source, i.e., as a shared constant current source, for the multiple differential pairs 36₁ through 36ₙ.

The multiple differential conversion circuits 38₁ through 38ₙ are respectively provided to the multiple paths 12₁ through 12ₙ. The i-th differential conversion circuit 38, is configured to convert the output signal Sbᵢ of the corresponding timing adjustment circuit 20ᵢ into a differential signal PATi and PATix, to output one component the differential signal, i.e., PATi, to the control terminal (gate) of the first transistor Mᵢ₁ of the corresponding differential pair 36ᵢ, and to output the other component of the differential signal, i.e., PATix, to the control terminal (gate) of the second transistor Mᵢ₂ of the corresponding differential pair 36ᵢ.

The combining output circuit 30a shown in FIG. 3 has a single-ended configuration. With such an arrangement, the signal output via the second terminal of the second resistor R2 is output to the transmission line 3.

A modification may be made in which the combining output circuit 30a has a differential configuration. In this case, the combining output circuit 30a may output a pair composed of a signal output via the second terminal of the second resistor R2 and a signal output via the second terminal of the first resistor R1 as a differential output signal.

With the driver circuit 100a shown in FIG. 3, the output stage has a CML-type configuration, the differential pairs 36₁ through 36ₙ are respectively provided to the paths 12₁ through 12ₙ, and the currents that flow through the respective differential pairs 36 are combined. Thus, such an arrangement is capable of appropriately combining the output signals Sb₁ through Sbₙ of the respective multiple timing adjustment circuits 20₁ through 20ₙ. Such a configuration provides an advantage of allowing the driver circuit 100a to output a high-speed signal, e.g., at several Gbps. In addition, such a configuration provides an advantage of very high compatibility with the CMOS process.

Furthermore, in a case in which the transistor sizes of the respective differential pairs 36₁ through 36ₙ are weighted, such an arrangement is capable of changing the coefficients for when the signals Sb₁ through Sbₙ are to be combined, according to the weighting factors. It should be noted that all the differential pairs 36₁ through 36ᵢ may have the same transistor size.

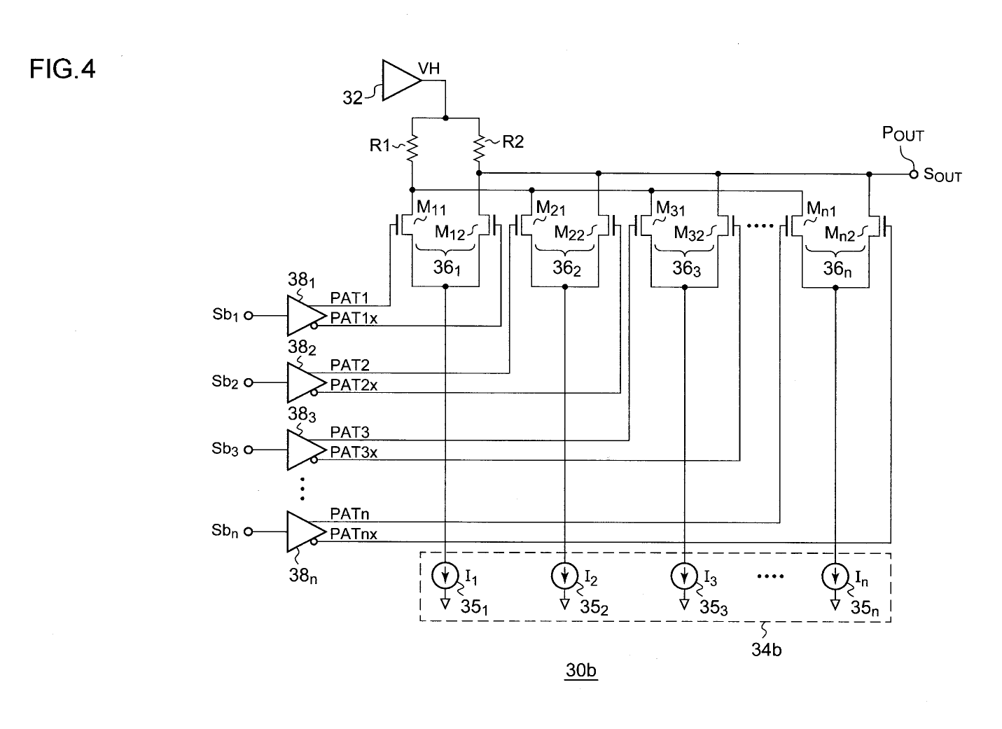

FIG. 4 is a circuit diagram which shows a modification of the combining output circuit 30a shown in FIG. 3. With such a combining output circuit 30b shown in FIG. 4, the second terminals (sources) of the respective differential pairs 36 are provided in a respectively independent manner for the paths 12₁ through 12ₙ. With such an arrangement, the constant current circuit 34b includes current sources 35₁ through 35ₙ respectively provided to the differential pairs 36₁ through 36ₙ. The i-th current source 35ᵢ supplies a tail current Iᵢ to the corresponding differential pair 36ᵢ.

Such a configuration shown in FIG. 4 provides the same advantages as those of the combining output circuit 30a shown in FIG. 3. Also, the differential pairs 36₁ through 36ₙ may have the same size. Alternatively, the sizes of the differential pairs 36₁ through 36ₙ may be weighted.

Moreover, the tail currents I₁ through Iₙ may have the same magnitude. Alternatively, the magnitudes of the tail currents I₁ through Iₙ may be weighted. By weighting the currents, such an arrangement is capable of changing the coefficients for when the multiple signals Sb₁ through Sbₙ are combined.

Description will be made below regarding several modifications.

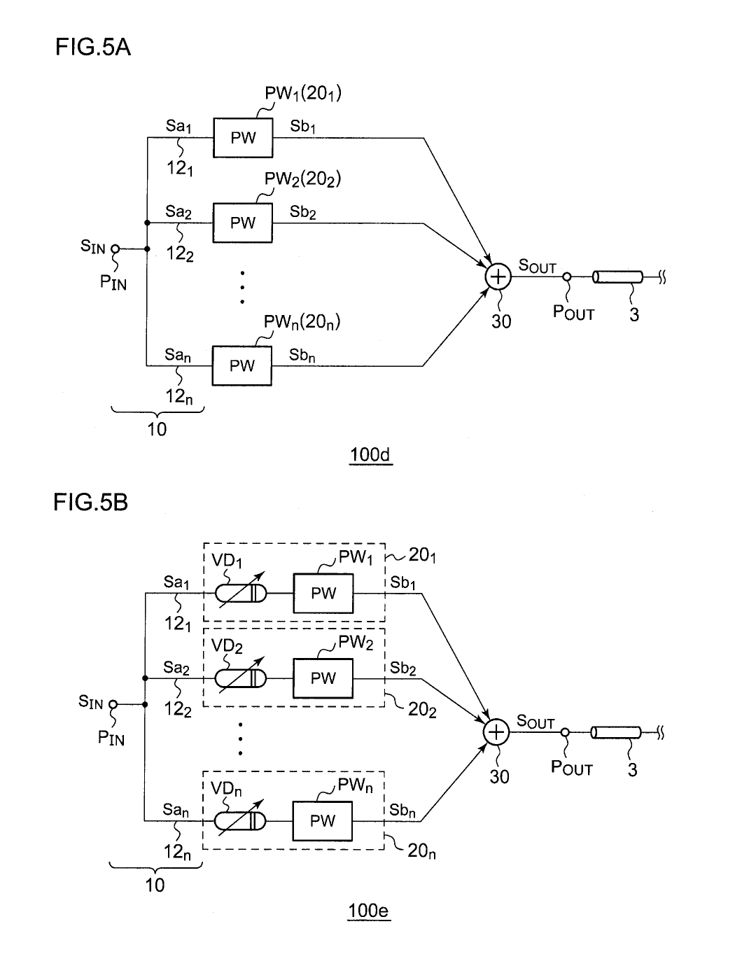

Description has been made regarding an arrangement in which each timing adjustment circuit 20 includes a variable delay circuit VD. However, the present invention is not restricted to such an arrangement. FIGS. 5A and 5B are block diagrams respectively showing a driver circuit 100d according to a first modification and a driver circuit 100e according to a second modification.

With the driver circuit 100d shown in FIG. 5A, each timing adjustment circuit 20 includes a pulse width adjustment circuit PW. The pulse width adjustment circuit PW applies a first delay amount to a positive edge of the input signal, and applies a second delay amount to a negative edge of the input signal. That is to say, the pulse width adjustment circuit PW applies separate delays to the positive edge and the negative edge, thereby adjusting the pulse width of the input signal. As such a pulse width adjustment circuit, such an arrangement may employ a circuit described in the pamphlet International Publication WO 2005/069487, etc., for example. Alternatively, circuits having other different configurations may be employed.

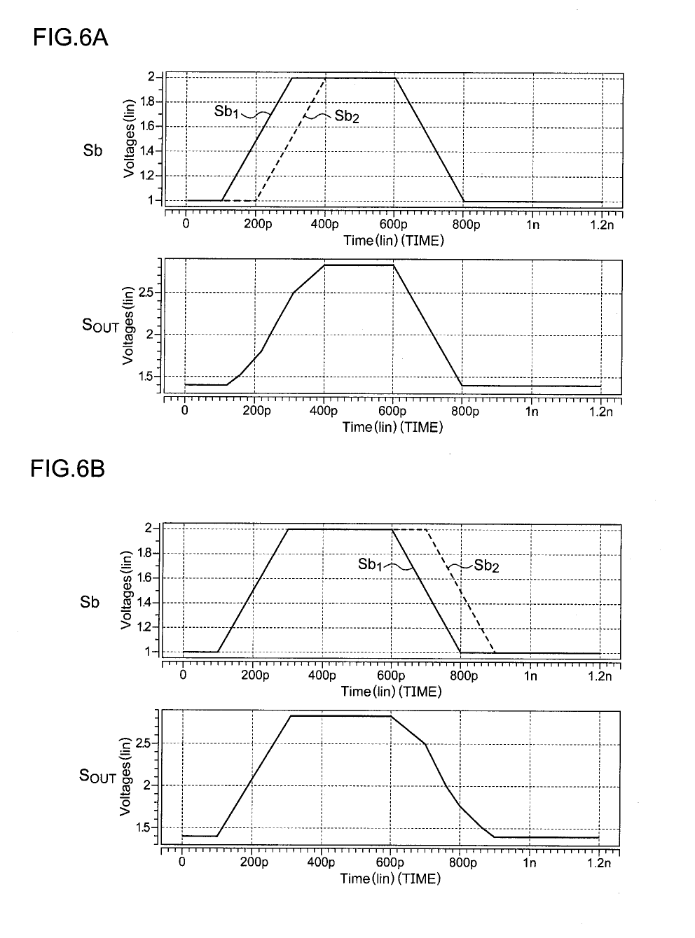

FIGS. 6A and 6B are time charts each showing the operation of the driver circuit 100d shown in FIG. 5A. FIGS. 6A and 6B each show an arrangement in which n=2. FIG. 6A shows an arrangement in which each positive edge is delayed, and FIG. 6B shows an arrangement in which each negative edge is delayed. By applying separate delays to the positive edge and the negative edge, such an arrangement is capable of independently controlling the positive edge waveform and the negative edge waveform.

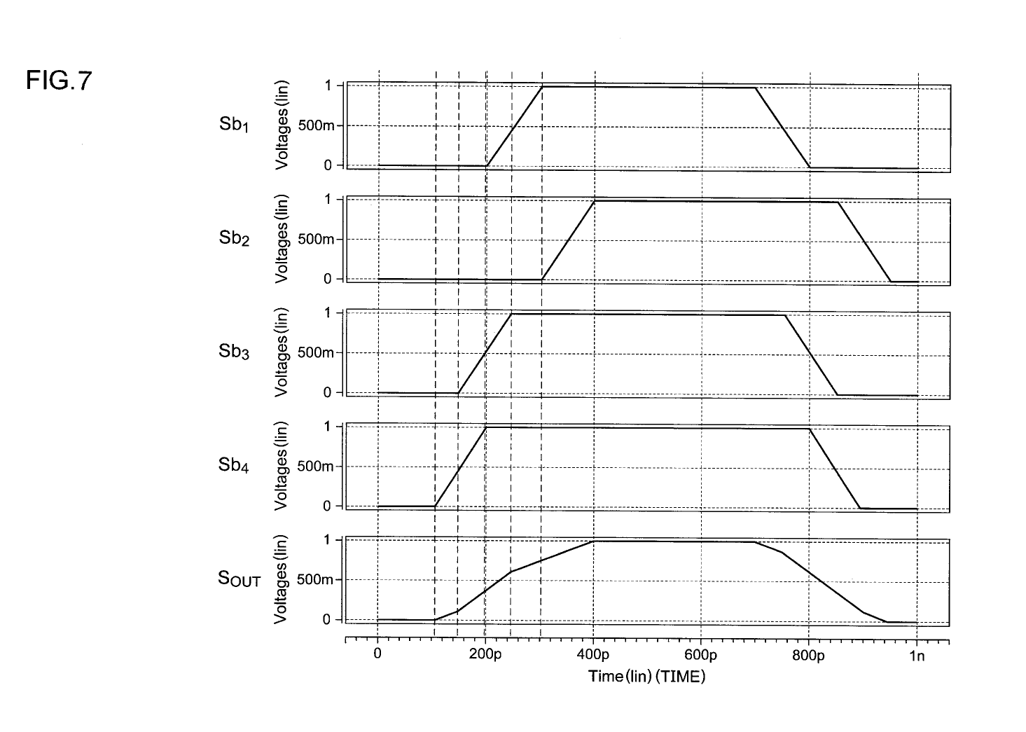

Returning to FIG. 5B, description will be made regarding the second modification. With the driver circuit 100e shown in FIG. 5B, each timing adjustment circuit 20 includes a variable delay circuit VD and a pulse width adjustment circuit PW connected in series. FIG. 7 is a time chart which shows the operation of the driver circuit 100e shown in FIG. 5B.

By configuring each timing adjustment circuit 20 as a combination of the variable delay circuit VD and the pulse width adjustment circuit PW, such an arrangement provides more flexible waveform control.

Furthermore, an arrangement may be made in which the timing adjustment circuits 20 assigned to certain paths are each configured as such a variable delay circuit VD, and the timing adjustment circuits 20 assigned to the other paths are each configured as such a pulse width adjustment circuit PW.

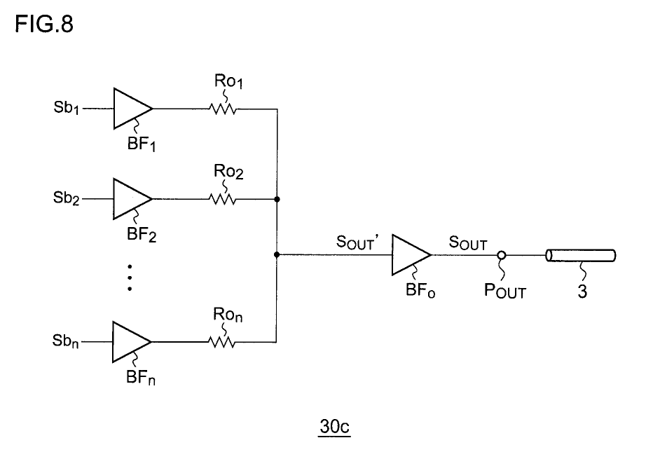

FIG. 8 is a circuit diagram which shows another example configuration of the combining output circuit. A combining output circuit 30c shown in FIG. 8 includes multiple buffer circuits BF₁ through BFₙ, multiple combining resistors Ro₁ through Roₙ, and an output buffer BFₒ.

The multiple buffer circuits BF₁ through BFₙ are respectively provided to the multiple paths 12₁ through 12ₙ (not shown). The i-th buffer circuit BFᵢ is configured to receive an output signal Sbᵢ of the corresponding timing adjustment circuit 20ᵢ. The multiple buffer circuits BF₁ through BFₙ may each have the same gain, or may have different respective gains. The gains of the buffer circuits BF determine the coefficients for the combination of the signals.

The multiple combining resistors Ro₁ through Roₙ are respectively provided to the multiple paths 12₁ through 12ₙ. The i-th combining resistor Roᵢ receives, via its first terminal, an output signal of the corresponding buffer circuit BFᵢ. The second terminals of the respective multiple combining resistors Ro₁ through Roₙ are connected together so as to form a common second terminal. The output buffer BFₒ is configured to receive a signal S_{OUT}′ output via the common second terminal thus obtained by connecting together the second terminals of the respective multiple combining resistors Ro₁ through Roₙ, and to output the corresponding output signal S_{OUT} to the transmission line 3. The multiple combining resistors Ro₁ through Roₙ may each have the same resistance, or may have different respective resistances.

With the combining output circuit 30c shown in FIG. 8, with the gains of the respective buffer circuits BF₁ through BFₙ as g₁ through gₙ, the following expression holds true based upon the conservation law of current.

(Sb₁×g₁−S_{OUT}′)/Ro₁+(Sb₂×g₂−S_{OUT}′)/Ro₂+ . . . =Σ_{i-1:n}{(Sbᵢ×gᵢ−S_{OUT}′)/Roᵢ}=0 (1)

Expression (1) is solved with respect to S_{OUT}′, thereby obtaining the following Expression (2).

Σ_{i=1:n}(Sbᵢ×gᵢ/Roᵢ)=Σ_{i=1:n}(S_{OUT}′/Roᵢ)

S_{OUT}′=Σ_{i=1:n}(Sbᵢ×gᵢ/Roᵢ)/Σ_{i=1:n}Roᵢ (2)

That is to say, according to the combining resistors Ro₁ through Roₙ and the gains g₁ through gₙ, such an arrangement is capable of adjusting the coefficients for when the signals Sbᵢ through Sbₙ are combined.

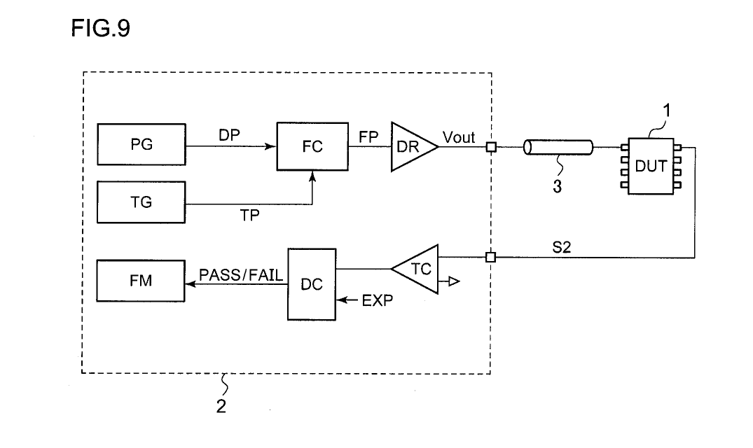

Lastly, description will be made regarding an application of the driver circuit according to the first embodiment or the second embodiment. FIG. 9 is a block diagram which shows a configuration of a test apparatus 2 including a driver circuit according to an embodiment.

The test apparatus 2 mainly includes a pattern generator PG, a timing generator TG, a waveform shaper FC, a driver DR, a timing comparator TC, and a logical comparator DC.

The pattern generator PG is configured to generate pattern data DP which determines a test pattern to be supplied to a DUT 1. For each predetermined period (which will be referred to as the “rate period T_{RATE}” hereafter), the timing generator TG generates timing setting data TP for setting a positive edge timing and a negative edge timing of a signal V_{OUT} to be supplied to the DUT 1 according to the pattern data DP.

The waveform shaper FC receives the pattern data DP and the timing setting data TP, and generate an output signal FP having a value that changes at a timing that corresponds to the pattern data DP and the timing setting data TP thus received. The driver DR is configured as such a driver circuit 100 according to the aforementioned embodiment, and is configured to output, to the DUT 1, a voltage Vₒᵤₜ having a level that corresponds to the signal FP received from the waveform shaper FC.

The timing comparator TC is configured to receive a signal S2 output from the DUT 1, and to latch the value of the signal S2 at a predetermined timing. For each test cycle, the logical comparator DC digitally compares the output values of the timing comparator TC with respective corresponding expected values EXP, and generates a pass/fail signal PASS/FAIL which indicates whether or not each output value agrees or disagrees with the corresponding expected value EXP. The pass/fail signal is stored in fail memory FM.

The above is an example configuration of the test apparatus 2. By mounting the driver circuit 100 according to the embodiment on such a test apparatus 2, such an arrangement is capable of adjusting the waveform of a signal supplied to the DUT 1 as desired according to the kind of DUT 1 and the test item.

While the preferred embodiments of the present invention have been described using specific terms, such description is for illustrative purposes only, and it is to be understood that changes and variations may be made without departing from the spirit or scope of the appended claims.

What is claimed is:

1. A driver circuit configured to output a signal to a transmission line, the driver circuit comprising:
a branch circuit configured to branch a signal to be transmitted into a plurality of paths;
a plurality of timing adjustment circuits, respectively provided to the plurality of paths, which are each configured to apply a delay to at least one from among a positive edge and a negative edge of the signal to be transmitted thus branched into a corresponding path; and
a combining output circuit configured to combine output signals of the plurality of timing adjustment circuits, and to output the combined signal to the transmission line.

2. A driver circuit according to claim 1, wherein the combining output circuit comprises:
a voltage source configured to generate a predetermined voltage;
a first resistor configured to receive the predetermined voltage via its first terminal;
a second resistor configured to receive the predetermined voltage via its first terminal;
a plurality of differential pairs, provided to the plurality of respective paths, which each comprise a first transistor arranged such that its first terminal is connected to a second terminal of the first resistor, and a second transistor arranged such that its first terminal is connected to a second terminal of the second resistor and its second terminal is connected to a second terminal of the first transistor so as to form a common second terminal;
a constant current circuit configured to supply a tail current to the plurality of differential pairs; and
a plurality of differential conversion circuits, provided to the plurality of respective paths, which are each configured to convert an output signal of the corresponding timing adjustment circuit into a differential signal, to output one component of the differential signal to a control terminal of the first transistor that forms the corresponding differential pair, and to output the other component of the differential signal to a control terminal of the second transistor that forms the corresponding differential pair.

3. A driver circuit according to claim 2, wherein the constant current circuit comprises a single constant current source that is shared by the plurality of differential pairs.

4. A driver circuit according to claim 2, wherein the constant current circuit comprises a plurality of constant current sources, provided to the plurality of respective differential pairs, which are each configured to supply a predetermined tail current to the corresponding differential pair.

5. A driver circuit according to claim 2, wherein the combining output circuit is configured to output, to the transmission line, a signal that is output from the second terminal of the second resistor.

6. A driver circuit according to claim 2, wherein the combining output circuit is configured to output, to a differential transmission line, a signal that is output from the second terminal of the second resistor and a signal that is output from the second terminal of the first resistor.

7. A driver circuit according to claim 2, wherein the combining output circuit comprises:
a plurality of buffer circuits, provided to the plurality of respective paths, which are each configured to receive an output signal of the corresponding timing adjustment circuit;
a plurality of combining resistors, provided to the plurality of respective paths, which are each arranged such that an output signal of the corresponding buffer circuit is received via a first terminal of the corresponding combining resistor, and such that their second terminals are connected together so as to form a common second terminal; and
an output buffer configured to receive a signal output via the common second terminal obtained by connecting together the second terminals of the plurality of combining resistors, and to output the signal thus received to the transmission line.

8. A driver circuit according to claim 1, wherein the timing adjustment circuit comprises a delay circuit configured to delay an input signal.

9. A driver circuit according to claim 1, wherein the timing adjustment circuit comprises a pulse width adjustment circuit configured to apply separate respective delays to a positive edge and a negative edge of the input signal, thereby adjusting the pulse width.

10. A driver circuit according to claim 1, wherein the timing adjustment circuits each comprise:
a delay circuit configured to delay an input signal; and
a pulse width adjustment circuit configured to apply separate delays to a positive edge and a negative edge of the input signal, thereby adjusting the pulse width of the signal,
and wherein the delay circuit and the pulse width adjustment circuit of each timing adjustment circuit are arranged in series on the corresponding path.

11. A test apparatus configured to test a device under test, the test apparatus comprising a driver circuit configured to output a signal that corresponds to a test pattern to the device under test via a transmission line,
wherein the driver circuit comprises:
a branch circuit configured to branch a signal to be transmitted into a plurality of paths;
a plurality of timing adjustment circuits, respectively provided to the plurality of paths, which are each configured to apply a delay to at least one from among a positive edge and a negative edge of the signal to be transmitted thus branched into a corresponding path; and
a combining output circuit configured to combine output signals of the plurality of timing adjustment circuits, and to output the combined signal to the transmission line.
